(19) United States
(12) Patent Application Publication
(10) Pub. No.: US 2024/0069263 A1
(43) Pub. Date: Feb. 29, 2024

(54) METHOD OF MANUFACTURING OPTICAL COMPONENT, APPARATUS OF MANUFACTURING OPTICAL COMPONENT AND OPTICAL COMPONENT

(71) Applicant: Ushio Denki Kabushiki Kaisha, Chiyoda-ku, Tokyo (JP)

(72) Inventors: Shigeki Matsumoto, Tokyo (JP); Shinji Suzuki, Tokyo (JP); Yohei Nawaki, Tokyo (JP)

(73) Assignee: Ushio Denki Kabushiki Kaisha, Chiyoda-ku, Tokyo, (JP)

(21) Appl. No.: 18/272,035

(22) PCT Filed: Mar. 3, 2022
(86) PCT No.: PCT/JP2022/009111

§ 371 Date: Jul. 12, 2023

(30) Foreign Application Priority Data
Mar. 9, 2021 (JP) 2021-037495

(51) Int. Cl. G02B 5/30

(52) U.S. Cl. CPC G02B 5/3016

(57) ABSTRACT

A method of manufacturing an optical component includes the steps of irradiating a base material that is substantially transparent to light having a wavelength for which the optical component is used with linearly polarized ultraviolet light having a wavelength of 200 nm or less, stacking a polymerizable liquid crystal compound on the base material after the irradiation with the linearly polarized ultraviolet light, and forming a retardation layer by allowing the polymerizable liquid crystal compound to be aligned in accordance with the state of the base material.

### TECHNICAL FIELD

The present disclosure relates to a method of manufacturing an optical component having a retardation layer.

### BACKGROUND ART

In the optical field, the phase control of light is an important technology. Waveplates such as quarter-wave plates and half-wave plates are widely used as optical components to control the phase of light. Waveplates are also referred to as retardation plates, retardation films, or retardation layers.

For example, liquid crystal displays, in principle, require a retardation film to control brightness. Organic EL displays require an anti-reflection film to suppress the reflection of external light, and the anti-reflection film has a layered structure consisting of a linear polarizer and a quarter-wave plate.

Retardation plates/retardation films used for applications such as display devices are required to provide a uniform phase difference for light over a wide wavelength band. In recent years, in order to meet the demand for thinner optical components, retardation films using polymerizable liquid crystal compounds have been proposed, as described in Patent Document 1, for example. Examples of polymerizable liquid crystal compounds include ultraviolet light-curable liquid crystal monomers (UV-curable liquid crystals) that are cured by irradiation with ultraviolet light.

The following is a description of the conventional manufacturing process for retardation films using conventional polymerizable liquid crystal compounds.

This manufacturing process involves applying a polymerizable composition containing a polymerizable liquid crystal compound onto a support that has been subjected to alignment properties, drying the solvent, and making the liquid crystal compound oriented and then polymerized by ultraviolet light or heat.

FIG. 1 is a cross-sectional view illustrating a conventional manufacturing method of an optical component 900 provided with a retardation film.

As shown in FIG. 1A, prepared is a base material 902 that supports an alignment film and a retardation layer to be illustrated later. Next, as shown in FIG. 1B, an alignment film 904 is applied onto the front surface of the base material 902. Then, as shown in FIG. 10, the alignment film 904 is subjected to alignment treatment that imparts alignment properties thereto. As alignment treatment, rubbing method, photo-alignment method, or other methods are used. FIG. 10 illustrates photo-alignment treatment. That is, the alignment film 904 is irradiated with linearly polarized ultraviolet light to perform the alignment treatment of the alignment film.

Next, as shown in FIG. 1D, a polymerizable liquid crystal compound 906 (e.g., an ultraviolet light-curable liquid crystal monomer, etc.) is deposited on the alignment film 904 that has been subjected to the alignment treatment by coating or other methods. The polymerizable liquid crystal compound 906 is aligned in accordance with the alignment of the alignment film 904, which serves as a base thereof.

Next, as shown in FIG. 1E, a laminate 910 of the base material 902, the alignment film 904, and the polymerizable liquid crystal compound 906, which has been created through the process in FIG. 1D, is heated. The polymerizable liquid crystal compound 906 is dried and fixed in a state where an alignment state is retained. Then, as shown in FIG. 1F, the aligned polymerizable liquid crystal compound 906 is irradiated with ultraviolet light. This heating or UV irradiation cures and fixes the polymerizable liquid crystal compound. As a result, the cured material of the polymerizable liquid crystal compound in which the alignment state is retained becomes a retardation layer 908.

Next, as shown in FIG. 1G, the retardation layer 908 of the laminate 910 is bonded to another optical element 920 (e.g., polarizing film).

Then, as shown in FIG. 1H, the retardation layer 908 is transferred to another optical element 920 by peeling off the base material 902 and the alignment film 904.

For example, when the retardation layer 908 is configured to function as a quarter-wave plate and the optical element 920 is a linear polarizer, the optical component 900 can include an anti-reflection film.

### CITATION LIST

Patent Document 1: JP-A-2020-086397

### SUMMARY OF INVENTION

### Technical Problem

In the conventional manufacturing process of the optical component 900, an alignment film 904 is used as a base to allow the polymerizable liquid crystal compound 906 to be aligned.

The rubbing method or the photo-alignment method is used for the alignment treatment of the alignment film 904. Here, the photo-alignment method has the following advantages over the rubbing method. Unlike the rubbing method, the photo-alignment method is a non-contact treatment and does not generate dust or static electricity, thus improving yield rates. In addition, the photo-alignment method can perform alignment treatment on minute areas that cannot be handled by the rubbing method.

For this reason, special films capable of photo-alignment treatment are often employed as alignment films. However, since the material of films capable of photo-alignment treatment is expensive, it is a factor that increases the cost of the optical component 900.

In addition, the deposition process of the alignment film 904 on the base material 902 is required before the polymerizable liquid crystal compound 906 is aligned, resulting in increasing the manufacturing cost.

The present disclosure has been made in view of the problems related to the above, and one exemplary object of an aspect thereof is to provide a method of manufacturing an optical component having a retardation film that is simpler than conventional methods thereof.

### Solution to Problem

A method of manufacturing an optical component according to an aspect of the present disclosure includes the steps of irradiating a base material that is substantially transparent to light having a wavelength for which the optical component is used with linearly polarized ultraviolet light having a wavelength of 200 nm or less, stacking a polymerizable liquid crystal compound on the base material after the irradiation with the linearly polarized ultraviolet light, and forming a retardation layer by allowing the polymerizable liquid crystal compound to be aligned.

Another aspect of the present disclosure is an apparatus of manufacturing an optical component. The apparatus includes a conveying means that conveys a base material that is a resin excluding polycarbonate and substantially transparent to light having a wavelength for which the optical component is used, and an illumination device that irradiates the base material with linearly polarized ultraviolet light having a wavelength of 200 nm or less.

The optical component according to one embodiment includes a base material made of at least one of PET, TAC, and cyclic olefin polymer (also referred to as COP, COC, COR) and a polymerizable liquid crystal compound that is directly laminated on the base material without any other layer and that is at least partially aligned in accordance with the state of the base material.

Note that any combination of the above components, and any mutual substitution of the components and expressions of the present disclosure among methods, devices, systems, and the like are also valid as aspects of the present disclosure.

### Effects of the Invention

An aspect of the present disclosure is capable of manufacturing an optical component with a retardation layer more easily than before.

### BRIEF DESCRIPTION OF DRAWINGS

FIGS. 1A to 1H are each a cross-sectional view illustrating a conventional method of manufacturing an optical component including a retardation film.

FIGS. 2A to 2F are each a cross-sectional view illustrating a method of manufacturing an optical component according to an embodiment.

FIG. 3 is a flowchart of the manufacturing method according to an embodiment.

FIGS. 4A to 4D are each a cross-sectional view illustrating a method of manufacturing an optical component.

FIGS. 5A and 5B are each a diagram illustrating a liquid crystal cell structure for evaluation, including a test film to be evaluated.

FIG. 6 is a cross-sectional view of an evaluation system.

FIGS. 7A and 7B are each a photograph illustrating a reference test film.

FIGS. 8A to 8C are each a schematic diagram of a photo-alignment treatment system in which the test film is irradiated with polarized ultraviolet light to be subjected to photo-alignment treatment.

FIGS. 9A to 9C are each a graph illustrating an emission spectrum of Xe excimer lamps, KrCl excimer lamps, and Deep-UV lamps, respectively.

FIG. 10 is a graph illustrating the extinction ratio and transmittance characteristics of a VUV polarizer.

FIG. 11 is a graph illustrating the extinction ratio and transmittance characteristics of a DUV polarizer.

FIG. 12 is a table including the photographs of samples #11 to #15 using a TAC film.

FIG. 13 is a table including the photographs of samples #21 to #27 using PET films.

FIG. 14 is a table including the photographs of samples #31 to #35 using COP films.

FIG. 15 is a table including the photographs of samples #41 to #45 using PC films.

FIG. 16 is a table including the photographs of samples #51 to #59 using PET films and samples #61 to #64 using PI films.

FIG. 17 is a table indicating a list of results for the samples prepared with different materials and conditions.

FIGS. 18A and 18B are each a schematic diagram illustrating a manufacturing apparatus.

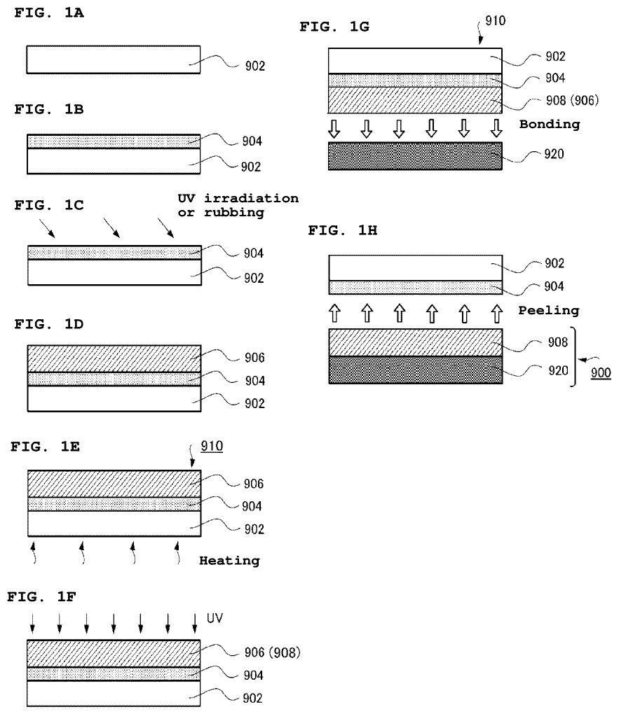

### DESCRIPTION OF EMBODIMENTS

Hereinafter, an overview of some exemplary embodiments of the present disclosure will be described. This overview is intended as a preface to the detailed description that follows, to provide a simplified description of some concepts of one or more embodiments for the purpose of a basic understanding of the embodiments, and is not intended to limit the breadth of the invention or disclosure. This overview is not a comprehensive summary of all conceivable embodiments, nor does it limit the indispensable component of the embodiments. For convenience, “an embodiment” may be used to refer to one embodiment (Example or Variation Example) or a plurality of embodiments (Examples or Variation Examples) disclosed in the present specification.

The inventors focused on the base material constituting the retardation layer and attempted to perform alignment treatment to provide alignment properties to the base material itself. As a result, it was found that it is possible to impart alignment properties directly to the base material itself by irradiating a specified material used for an optical component (e.g. optical film) with linearly polarized ultraviolet light having a wavelength of 200 nm or less (222 nm or 254 nm depending on the base material).

In other words, the inventors have found a method of manufacturing an optical component (a method of imparting alignment properties) capable of including a retardation layer on the substrate by allowing a polymerizable liquid crystal compound to be aligned on the base material as a base, without using an alignment film formed on the base material as a base, the retardation layer being constituted by a cured material of the polymerizable liquid crystal compound in which the alignment state is retained.

The method of manufacturing an optical component according to one embodiment includes the steps of irradiating a base material that is substantially transparent to light having a wavelength for which the optical component is used with linearly polarized ultraviolet light having a wavelength of 200 nm or less, stacking a polymerizable liquid crystal compound on the base material after the irradiation with the linearly polarized ultraviolet light, and forming a retardation layer by allowing the polymerizable liquid crystal compound to be aligned in accordance with the state of the base material.

This method is capable of imparting orientation properties to the base material by the irradiation with the linearly polarized ultraviolet light having a wavelength of 200 nm or less. Then, using the aligned base material as a base and stacking the polymerizable liquid crystal compound make it possible to provide alignment properties to the polymerizable liquid crystal compound in accordance with the state of the base material to form the retardation layer. This method eliminates the need for (i) expensive materials for an alignment film and (ii) processes for applying and curing an alignment film, thereby simplifying the process and lowering the production cost.

In one embodiment, since the base material is transparent, the layered structure of the base material and retardation layer can be used as an optical element as it is. In this case, the base material does not need to be peeled off, thus further reducing the manufacturing cost.

In one embodiment, the retardation layer may be aligned in a direction parallel to the polarization direction of the linearly polarized ultraviolet light. The materials of the film (alignment film) capable of photo-alignment treatment used in the conventional technology are oriented in a direction perpendicular to the direction of polarization of the linearly polarized ultraviolet light, and the mechanism of the alignment treatment in one embodiment is different from that of conventional materials.

In one embodiment, the photochemical reaction of the base material induced by the irradiation with the linearly polarized ultraviolet light may be a decomposition reaction. The materials of the film (alignment film) capable of photo-alignment treatment used in the conventional technology are based on cross-linking or polymerization reactions, and it can be said that the mechanism of the alignment treatment in one embodiment is different from that of conventional materials.

In one embodiment, the base material may be made of one of PET (polyethylene terephthalate), TAC (triacetylcellulose), and cyclic olefin polymer. Since PET and TAC are inexpensive and readily available, using these materials enables further cost reduction.

In one embodiment, the polymerizable liquid crystal compound may have abnormal dispersion properties. This allows the properties of the optical component to be made uniform over the entire visible light range.

In one embodiment, the irradiation with the linearly polarized ultraviolet light may be performed in an inert gas atmosphere.

In one embodiment, the base material may be made of PET. The step of the irradiation with the linearly polarized ultraviolet light may be the irradiation with linearly polarized ultraviolet light having a wavelength of 222 nm or 254 nm instead of the linearly polarized ultraviolet light having a wavelength of 200 nm or less.

In one embodiment, the base material may be made of PET, and the irradiation with the linearly polarized ultraviolet light may be performed in an atmosphere containing oxygen.

An apparatus of manufacturing an optical component according to one embodiment includes a conveying means that conveys a base material that is substantially transparent to light having a wavelength for which the optical component is used, and an illumination device that irradiates the base material with linearly polarized ultraviolet light having a wavelength of 200 nm or less. The manufacturing apparatus may further include a coating device that applies a polymerizable liquid crystal compound to the base material after the irradiation with the linearly polarized ultraviolet light.

An optical component according to one embodiment includes a base material that is made of at least one of PET, TAC, and cyclic olefin polymer, and a polymerizable liquid crystal compound that is directly stacked on the base material without any other layer and that is at least partially aligned. The molecules constituting the base material may be decomposed rather than polymerized or cross-linked.

### Embodiments

Hereinafter, suitable embodiments will be described with reference to the drawings. Identical or similar components, members, and processes shown in the respective drawings will be marked with the same symbols, and duplicate descriptions will be omitted as appropriate. The embodiments are exemplary rather than limiting the disclosure or invention, and all features and combinations thereof described in the embodiments are not necessarily essential to the disclosure or invention.

In addition, the dimensions (thickness, length, width, etc.) of each member described in the drawings may be magnified or reduced as appropriate for ease of understanding. Furthermore, the dimensions of a plurality of members do not necessarily represent their size relationship, and even if one member A is illustrated thicker than another member B in the drawings, the member A may be thinner than the member B.

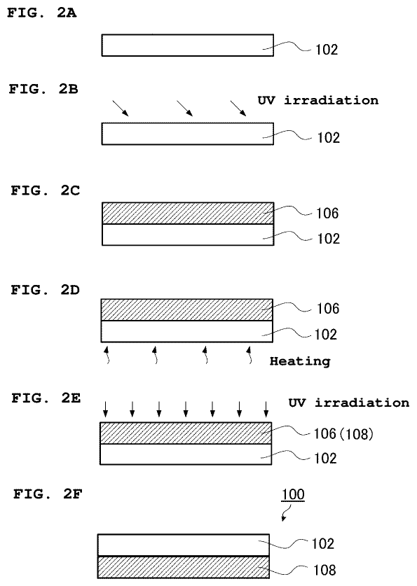

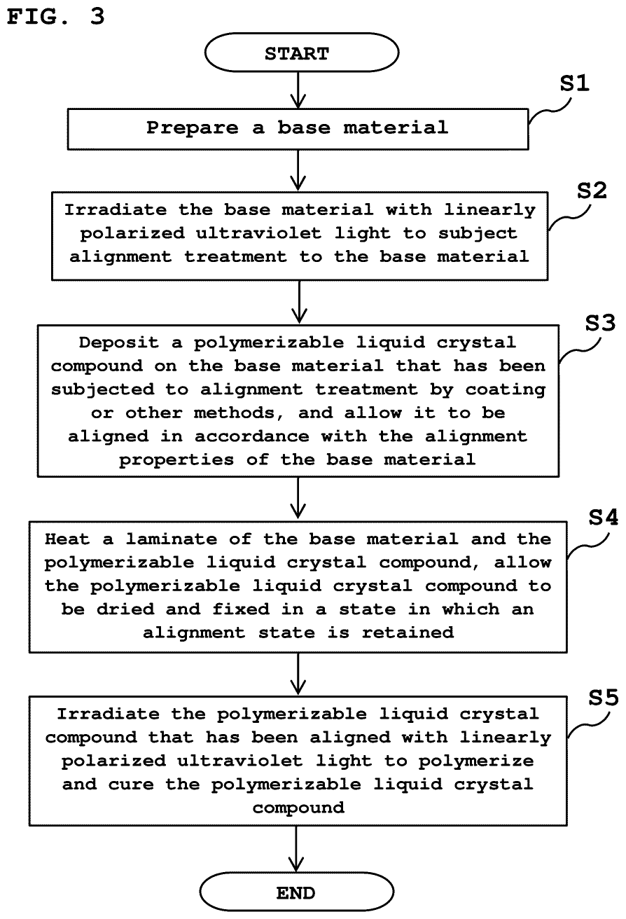

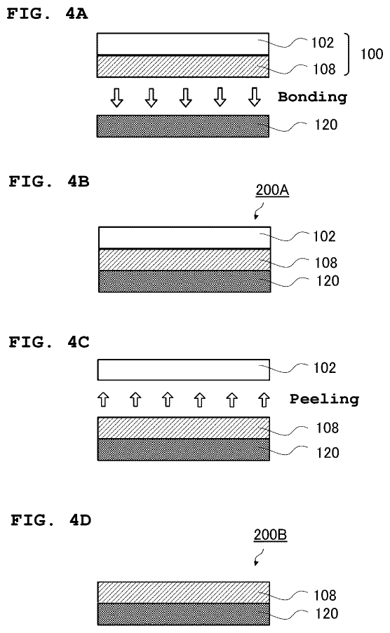

FIGS. 2A to 2F are each a cross-sectional view illustrating a method of manufacturing an optical component according to an embodiment. FIG. 3 is a flowchart of the manufacturing method according to an embodiment.

As shown in FIG. 2A, first, a base material 102 supporting a retardation layer 108 that will be described later is prepared (process S1 in FIG. 3).

The base material 102 is made of a resin material that is given alignment properties by the irradiation of linearly polarized ultraviolet light, which is discovered by the inventors. Since the above-mentioned base material 102 is used as a base material for an optical element, the resin material thereof is preferably a material having light transparency for visible light, especially a material having colorless transparency.

The transparent base material 102 that is capable of photo-alignment preferably has a transmittance of 50% or more in the visible light region, and more preferably 80% or more.

Next, as shown in FIG. 2B, the surface of the base material prepared in the treatment S1 is irradiated with linearly polarized ultraviolet light having a wavelength of 200 nm or less (hereinafter referred to as linearly polarized vacuum ultraviolet (VUV) light) to subject the alignment treatment to the base material 102 (treatment S2).

As the ultraviolet light source, a Xe excimer lamp emitting ultraviolet light with a central wavelength of 172 nm can be used. In addition, an excimer laser with a wavelength of 193 nm may be used instead of an excimer lamp.

Next, as shown in FIG. 2C, a polymerizable liquid crystal compound 106 (e.g., ultraviolet light-curable liquid crystal monomer, etc.) is deposited on the base material 102 that has been subjected to alignment treatment by coating or other methods. The polymerizable liquid crystal compound 106 is then made to be aligned in accordance with the alignment properties of the base material 102 (process S3), which serves as a base.

Then, as shown in FIG. 2D, a laminate 110 of the base material 102 and the polymerizable liquid crystal compound 106 is heated (process S4), allowing the polymerizable liquid crystal compound 106 to be dried and fixed in a state in which an alignment state is retained. As the heating method, any known heating and drying method may be selected as appropriate.

As shown in FIG. 2E, the polymerizable liquid crystal compound 106 that has been aligned is then irradiated with ultraviolet light (e.g., 365 nm) to polymerize and cure the polymerizable liquid crystal compound 106 (treatment S5). This makes it possible to achieve the retardation layer 108 constituted by a cured material of the polymerizable liquid crystal compound in which the alignment state is retained, as shown in FIG. 2F.

As described above, an optical component (retardation film) 100 including the transparent base material 102 and the retardation layer 108 is obtained. This optical component 100 may be used as a final product.

Alternatively, the optical component 100 may be used as an intermediate material (component) for another optical component 200. FIGS. 4A to 4D are each a cross-sectional view illustrating a method of manufacturing optical component 200. For example, the retardation layer 108 may be bonded to another optical element to form another optical component 200.

As shown in FIG. 4A, the retardation layer 108 of the optical component 100 is bonded to another optical element 120. The optical component with a state shown in FIG. 4B may finally become an optical component 200A. Since the base material 102 is transparent, the optical component 200A fails to lose the function even if the base material 102 is left as it is.

Alternatively, in a case where a thinner optical component is required, the base material 102 may be peeled off as shown in FIG. 4C, and the layered structure of the retardation layer 108 and the optical element 120 as shown in FIG. 4D may finally become an optical component 200B.

For example, when the retardation layer 108 is configured to function as a quarter-wavelength plate, this retardation layer 108 can be bonded to or transferred to the optical element 120, which is a linear polarizer, to form an anti-reflection film.

The method of manufacturing an optical component according to the embodiment has been described above.

Next, samples produced using this manufacturing method and their evaluation will be described.

### Evaluation of Photo-Alignment Base Material

First, the evaluation of the alignment produced on the base material by the irradiation of linearly polarized VUV light will be described.

### 1. Evaluation System

The inventors constructed an evaluation system for evaluating the quality of photo alignment of the base material irradiated with linearly polarized VUV light.

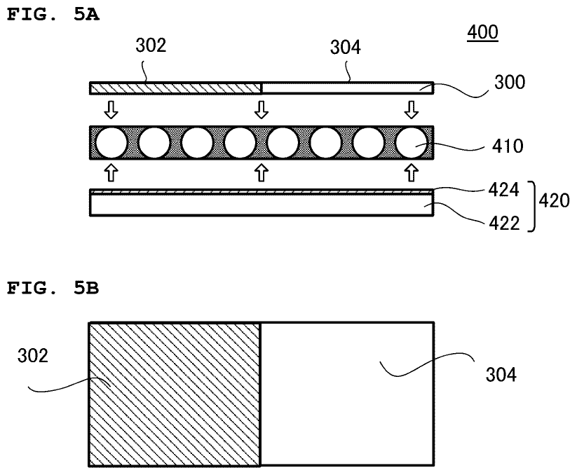

FIGS. 5A and 5B are each a diagram illustrating a liquid crystal cell structure 400 for evaluation, including a test film to be evaluated. A test film 300 simulates the base material 102 and is made of the same material as the base material 102. The test film 300 has its portion 302 (referred to as the photo-alignment area) that is subjected to alignment treatment by the irradiation of linearly polarized VUV light. The remaining portion 304 of the test film 300 (referred to as the non photo-alignment area) is the original resin material that is not irradiated with linearly polarized VUV light and is a reference area where no alignment treatment is performed.

As shown in FIG. 5A, the liquid crystal cell structure 400 includes a TN liquid crystal 410 and an alignment film substrate 420 in addition to the test film 300. The alignment film substrate 420 is obtained by forming an alignment film 424 on a glass substrate 422. The alignment film 424 is, for example, a polyimide (PI) coated film, and is given alignment properties by rubbing.

A 5CB (4-pentyl-4′-cyanobiphenyl) liquid crystal is dropped onto the alignment film substrate 420 to form a liquid crystal layer 410, and the base material to be evaluated (test film 300) is laminated on top of the layer.

After being irradiated with linearly polarized VUV light, the test film 300 is given alignment properties in accordance with the principle described above. The alignment of the liquid crystal layer 410 changes in accordance with the alignment state of the test film 300 that is in contact therewith. When the alignment direction of the liquid crystal layer 410 at the interface with the test film 300 is orthogonal to the alignment direction of the alignment film 424 of the alignment film substrate 420 disposed on the lower side thereof, the liquid crystal molecules in the liquid crystal layer 410 are twisted by 90 degrees, exhibiting an action that makes the polarization direction of polarized light passing through the liquid crystal layer 410 be rotated by 90 degrees. Hence, the liquid crystal cell structure 400 becomes a TN-type liquid crystal cell structure (hereinafter referred to as a TN cell structure). The liquid crystal layer 410 simulates the polymerizable liquid crystal compound 106 of the optical component 100.

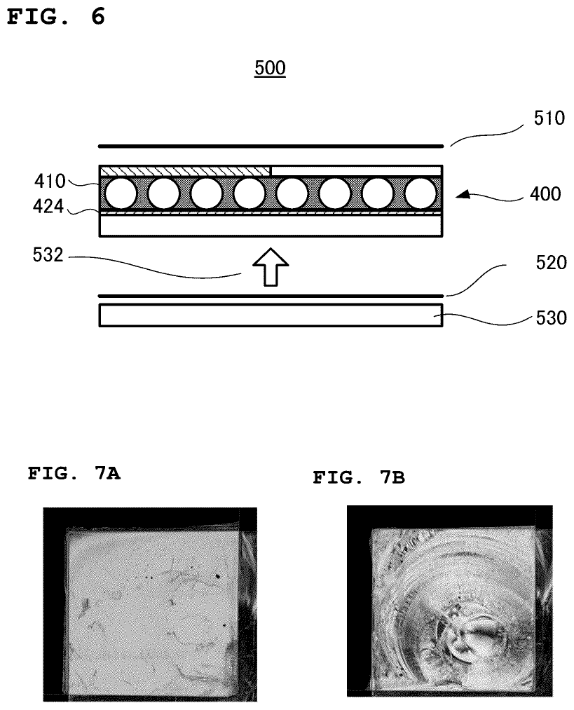

FIG. 6 is a cross-sectional view of an evaluation system 500. The evaluation system 500 includes a first polarizing film 510, a second polarizing film 520, and a backlight illumination 530 in addition to the liquid crystal cell structure 400. The liquid crystal cell structure 400 is sandwiched between the first polarizing film 510 and the second polarizing film 520.

The backlight illumination 530 is a trace stand with a fluorescent lamp inside, on which the second polarizing film 520 is disposed. The liquid crystal cell structure 400 is disposed on the upper part of the second polarizing film 520. The first polarizing film 510 is then disposed on the upper part of the liquid crystal cell structure 400. Here, the first polarizing film 510 and the second polarizing film 520 are arranged such that the polarization directions thereof are orthogonal (cross-nicol arrangement) each other.

When the alignment treatment given to the photo-alignment area 302 is good and the liquid crystal cell structure 400 functions as a TN cell structure, light emitted from the backlight illumination 530 becomes linearly polarized through the second polarizing film 520. When the linearly polarized light passes through the liquid crystal cell structure 400, the polarization direction of the light is rotated by 90 degrees to align the direction of the polarization axis of the first polarizing film 510. Hence, the light emitted from the backlight illumination 530 (backlight) passes through the first polarizing film 510.

In other words, when the liquid crystal cell structure 400 functions as a TN cell structure, if the alignment regulation force of the optical alignment area 302 described above is strong to align the liquid crystal molecules in the liquid crystal layer 410 in an orderly manner, the photo-alignment area 302 of the liquid crystal cell structure (TN cell structure) 400 appears white due to the light transmitted from the backlight illumination 530 when the liquid crystal cell structure 400 is viewed through the first polarizing film 510. Conversely, if the alignment regulation force of the photo-alignment area 302 is weak to fail to align the liquid crystal molecules in the liquid crystal layer 410 in an orderly manner, the photo-alignment area 302 appears non-uniform, such as liquid crystal drop marks, or halftone when the liquid crystal cell structure 400 is viewed through the first polarizing film 510.

Here, as a test film reference (referred to as a reference test film), a sample was prepared by coating a glass substrate with polyimide (PI: LX-1400 manufactured by Hitachi Chemical) and irradiating the polyimide with linearly polarized ultraviolet light having a wavelength 254 nm from a direction perpendicular to the surface of the polyimide.

This sample also has an area that is subjected to alignment treatment by the irradiation of polarized ultraviolet light having a wavelength of 254 nm and an area that has not been irradiated with polarized ultraviolet light having a wavelength of 254 nm.

The irradiation direction of the polarized ultraviolet light having a wavelength of 254 nm is perpendicular to the PI deposition surface.

The liquid crystal cell (TN cell) shown in FIG. 5A was fabricated using this reference test film, and was disposed in the evaluation system shown in FIG. 6, then the backlight illumination 530 was turned on.

FIGS. 7A and 7B are photographs illustrating the evaluation results of the reference test film. FIG. 7A is a photograph of the first polarizing film 510 of the reference test film overlapping the area that has been subjected to alignment treatment by the irradiation of polarized ultraviolet light having a wavelength of 254 nm, and FIG. 7B is a photograph of the first polarizing film 510 of the reference test film overlapping the area where no irradiation of polarized ultraviolet light having a wavelength of 254 nm has been performed.

In general, as described above, when PI (polyimide) is irradiated with vertically polarized ultraviolet light having a wavelength of 254 nm as described above, it is known that the liquid crystal is aligned but a pre-tilt angle fails to generate. The pre-tilt angle is an angle (rise angle) formed with the alignment film interface and the liquid crystal molecules that are in contact therewith. In the case of the rubbing method, the pre-tilt angle is generated by strongly rubbing in a certain direction and the liquid crystal molecules are aligned at the same angle in the same direction, resulting in a uniform screen without liquid crystal inversion, or in other words, disclination (line defect). In the case of the photo-alignment method, it is known that the pre-tilt angle is hardly generated by the irradiation from the vertical direction (i.e., the liquid crystal molecules are aligned nearly parallel to the alignment film surface). Hence, in the photo-alignment method, the irradiation of polarized light from the oblique direction with an offset angle from the vertical direction after the irradiation thereof from the vertical direction impart anisotropy to the liquid crystal molecules in the depth direction of the alignment film to generate a pre-tilt angle and to align the rise direction (two irradiation method). In previous reports, the photo-alignment method of PI (polyimide) layers using DUV polarized light involves radiating DUV polarized light with a polarization axis orthogonal to the desired alignment direction in the first irradiation from the vertical direction, and then radiating inclined DUV polarized light after rotating the polarization axis by 90 degrees from the first irradiation in the second irradiation to generate the pre-tilt angle because the alignment direction is orthogonal to the polarization axis. This is because anisotropy in the depth direction cannot be imparted (it becomes isotropy) without rotating the polarization axis by 90 degrees even if the light is tilted, and thus a pre-tilt angle cannot be generated. In the Example according to the present disclosure, since it is a purpose to confirm whether or not alignment properties are imparted, the evaluation was performed with only one irradiation from the vertical direction, thus generating no pre-tilt angle. Accordingly, disclination (line defect) is observed (areas that appear as black lines) in FIG. 7A; however, light passing through the evaluation liquid crystal cell structure 400 and the first polarizing film 510 appears white overall. In other words, it is confirmed that the reference test film was photo-aligned by the irradiation at a wavelength of 254 nm.

In contrast, as shown in FIG. 7B, which is the photograph of the area where no polarized ultraviolet light having a wavelength of 254 nm was irradiated to the PI, an overall non-uniformity is observed with having the drop marks of liquid crystal. This state indicates that the liquid crystal fails to be aligned in the area irradiated with no polarized ultraviolet light having a wavelength of 254 nm. Since the alignment properties have been imparted by rubbing in advance to the alignment film 424 on the glass substrate 422 located in the lower side of the liquid crystal layer 410 shown in FIG. 5A, FIG. 7B shows the non-uniformity caused only by the test film (PI sample) 300 located in the upper side of the liquid crystal layer 410 shown in FIG. 5A.

As described above, observing the test film using the evaluation system shown in FIG. 6 makes it possible to evaluate the alignment state and alignment regulation force of the photo-alignment area 302 of the test film.

### 2. Photo-Alignment Treatment System

Hereinafter, the device used to prepare the test film will be described.

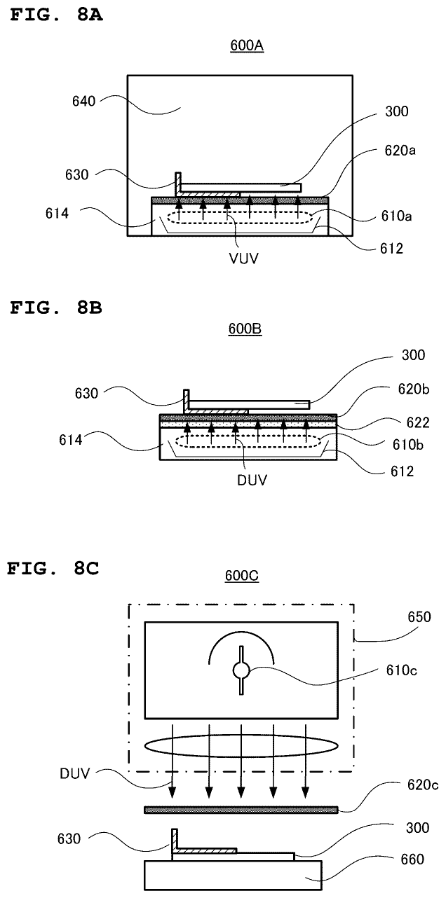

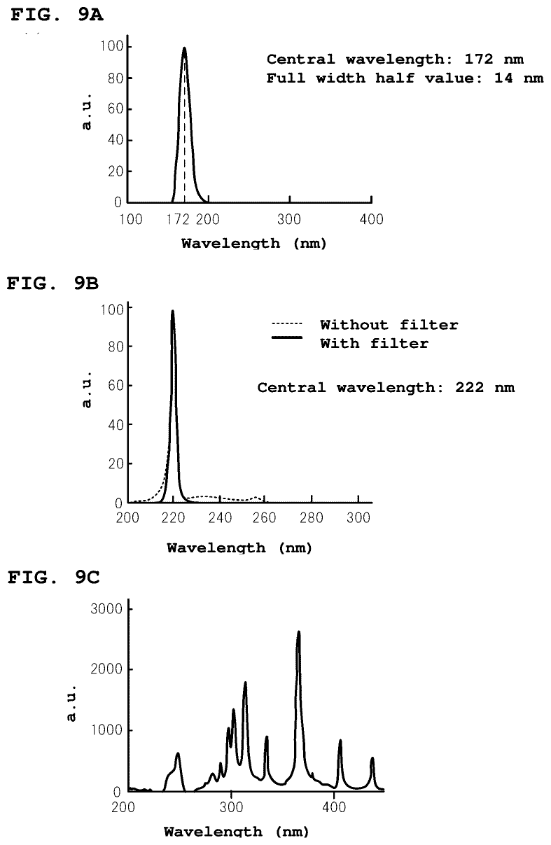

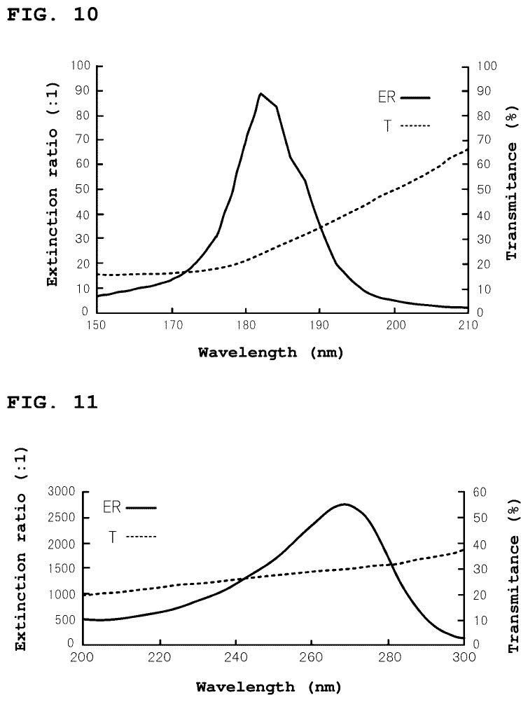

FIGS. 8A to 8C are each a schematic diagram of a photo-alignment treatment system 600 in which the test film is irradiated with polarized ultraviolet light to be subjected to photo-alignment treatment. As a light source, Xe excimer lamps, KrCl excimer lamps, or Deep-UV lamps (also referred to as super high-pressure mercury lamps or super high-pressure UV lamps) were used. FIGS. 9A to 9C are each a graph illustrating an emission spectrum of Xe excimer lamps, KrCl excimer lamps, and Deep-UV lamps, respectively.

A photo-alignment treatment system 600a shown in FIG. 8A uses a Xe excimer lamp 610a as a light source. As shown in FIG. 9A, the Xe excimer lamp 610a emits light having a center wavelength of 172 nm.

Referring back to FIG. 8A, the Xe excimer lamp 610a is located in a lamp house 614. A reflector 612 is provided in the lower side of the lamp house 614 (lower side in FIG. 8A). Hence, the light emitted from the Xe excimer lamp 610a travels upward from the lamp house 614 (in the direction of the arrows shown in FIG. 8A).

A polarizer for vacuum ultraviolet (VUV) light (hereinafter also referred to as a VUV polarizer) 620a is disposed on the light output aperture of the lamp house 614. FIG. 10 is a graph illustrating the extinction ratio and transmittance characteristics of the VUV polarizer 620a. In FIG. 10, the solid line indicates the extinction ratio characteristics and the dashed line indicates the transmittance characteristics.

The VUV polarizer 620a used in the present evaluation has an extinction ratio of 16:1 and a transmittance of 16% at the center wavelength of 172 nm of Xe excimer lamp light (measured with collimated light). As shown in FIG. 9A, the light emitted from the Xe excimer lamp 610a has a full width at half maximum (FWHM) of 14 nm, and the spectrum with a slightly longer hem on the longer wavelength side. The extinction ratio over a wavelength range from 165 to 179 nm, which is the full width at half maximum, ranges from 10:1 to 70:1. Hence, the average extinction ratio considering the wavelength distribution is approximately 25:1. Since a Xe excimer lamp is a divergent light source, the light has an oblique incidence component, thus the extinction ratio is reduced. Accordingly, the extinction ratio is lowered to approximately ⅕ to 1/10, which is considered to be in a range approximately from 5:1 to 3:1.

Referring back to FIG. 8A, an L-shaped light-shielding plate 630 is placed on the upper part of the VUV polarizer 620a. The L-shaped light-shielding plate 630 is an L-shaped angle made of bright aluminum alloys and has a thickness of 0.5 mm.

The flat portion of the L-shaped light-shielding plate 630 covers the area of the test film 300 that is to become the non photo-alignment area 304. Since light emitted from the Xe excimer lamp is blocked by the light-shielding plate 630, approximately half the area of the test film 300 is not irradiated with the light from the Xe excimer lamp. This allows the test film 300 to have the photo-alignment area 302 and non photo-alignment area 304.

The lamp house 614 including the Xe excimer lamp 610a, the VUV polarizer 620a, and the light-shielding plate 630 are disposed in a purge box 640. The purge box 640 is capable of purging the oxygen concentration in the purge box 640 to 0.1% or less with nitrogen (N₂) gas.

The photo-alignment treatment system 600A, which uses the Xe excimer lamp 610a, enables the light irradiation to the test film 300 in both of an air atmosphere and an oxygen-purged atmosphere. The irradiation of vacuum ultraviolet light in an air atmosphere results in an oxidizing atmosphere because active oxygen and ozone are generated by a photo-decomposition reaction of oxygen in the atmosphere.

A photo-alignment treatment system 600B shown in FIG. 8B uses a KrCl excimer lamp 610b as a light source.

The KrCl excimer lamp 610b is disposed in the lamp house 614. A reflector 612 is disposed in the lower side of the lamp house 614 (lower side in FIG. 8B). Hence, the light emitted from the KrCl excimer lamp 610b travels upward from the lamp house 614 (in the direction of the arrows shown in FIG. 8B).

A wavelength selection filter 622 is disposed in the upper part of the lamp house 614. FIG. 9B is a graph illustrating the spectral distribution of light emitted from KrCl excimer lamps. In FIG. 9B, the dashed line indicates the spectral distribution when no wavelength selection filter 622 is disposed, and the solid line indicates the spectral distribution when the wavelength selection filter 622 is disposed to allow the light to transmit the wavelength selection filter 622.

In both spectral characteristics, the light intensity at the peak wavelength is normalized to 100 (a.u.). As shown in FIG. 9B, light emitted from the KrCl excimer lamp has a center wavelength of 222 nm. The light has a full width at half maximum of 2 nm, which is a sharp spectrum with a narrower width than that of the Xe excimer lamp.

A polarizer for deep ultraviolet (DUV) light (hereinafter also referred to as a DUV polarizer) 620b is disposed on the light output surface of the wavelength selection filter 622. FIG. 11 is a graph illustrating the extinction ratio and transmittance characteristics of the DUV polarizer 620a. In FIG. 11, the solid line indicates the extinction ratio characteristics and the dashed line indicates the transmittance characteristics.

The DUV polarizer 620b used in the present evaluation has an extinction ratio of 685:1 at the center wavelength of 222 nm of KrCl excimer lamp light (measured with a collimated light beam). As mentioned above, since the full width at half maximum of the KrCl excimer lamp spectrum is as narrow as 2 nm, the extinction ratio does not change significantly in this wavelength range, and the average extinction ratio is approximately 700:1. Since a KrCl excimer lamp is a divergent light source, it is noted that a component incident obliquely onto the DUV polarizer 620b occurs. Hence, the actual extinction ratio is slightly lowered than the above and is considered to be in a range approximately from 140:1 to 70:1. The transmittance thereof was 23%.

Referring back to FIG. 8B, the L-shaped light-shielding plate 630 is disposed on the upper part of the DUV polarizer 620b, as in FIG. 8A. This light-shielding plate 630 allows the test film 300 to be formed with the photo-alignment area 302 and the non photo-alignment area 304.

When the KrCl excimer lamp 610b is used, the light irradiation to the test film 300 is performed in an air atmosphere because no photolysis of oxygen in the atmosphere occurs and no active oxygen and ozone are generated. This eliminates the need for the purge box 640 in the photo-alignment treatment system 600B using the KrCl excimer lamp 610b.

A photo-alignment treatment system 600C shown in FIG. 8C uses a Deep-UV lamp 610c as a light source. As the Deep-UV lamp 610c, a USH-250BY manufactured by USHIO INC. was used. The Deep-UV lamp 610c is mounted in a collimated light irradiation system 650 (MultiLight manufactured by USHIO LIGHTING INC.). The light emitted from the Deep-UV lamp 610c travels downward (in the direction of the arrows shown in FIG. 8C) from the collimated light irradiation system 650.

FIG. 9C is a graph illustrating the spectral distribution of light emitted from the Deep-UV lamp (USH-250BY). As shown in the figure, the Deep-UV lamp 610C emits light having a wavelength of 230 nm or more in the DUV area. It is known from past reports that the emission of mercury in the band from 230 to 260 nm is effective for PI (polyimide), and the emission in this wavelength band is the emission that spreads around the characteristic line of mercury at 254 nm. In this specification, the term “irradiation at a wavelength of 254 nm” herein refers to the emission in this band.

Referring back to FIG. 8C, a DUV polarizer 620c is disposed in the lower side (light irradiation side) of the collimated light irradiation system 650. The DUV polarizer 620c is equivalent to that used in the photo-alignment treatment system 600B shown in FIG. 8B. The extinction ratio and transmittance characteristics of the DUV polarizer 620c are shown in FIG. 11.

In the typical wavelength band from 230 to 260 nm used in conventional photo-alignment treatment, the extinction ratio is in a range approximately from 850:1 to 2300:1 (measured in a collimated light beam). In addition, the transmittance thereof is from 24% to 29%. Since the light incident from the collimated light irradiation system is a collimated light and has no oblique incident component, the extinction ratio fails to be reduced and the above-mentioned values can be applied as they are.

Referring back to FIG. 8C, a stage 660 supporting the test film 300 is provided in the lower part of the DUV polarizer 620c. The test film 300 is placed on the stage 660, and an L-shaped light-shielding plate 630 is disposed on the test film 300. The light-shielding plate 630 allows the test film 300 to have the photo-alignment area 302 and the non photo-alignment area 304.

When the Deep-UV lamp 610c is used, light irradiation of the test film 300 is performed in an air atmosphere, as is the case with the KrCl excimer lamp 610b. Hence, this eliminates the need for using the purge box 640 in the photo-alignment treatment system 600C using the Deep-UV lamp 610c.

### Experiment

The photo alignment was imparted to several different materials by using photo-alignment treatment systems 600A-600C to prepare the samples of test film 300. The samples were then evaluated.
TAC (triacetylcellulose)
PET (polyethylene terephthalate)
COP (Cyclo-Olefin Polymer)
PC (polycarbonate)
PI (polyimide) layer

### 1. Experiment Using TAC Films

### 1.1 Sample Preparation Conditions

Several samples were prepared using TAC films (hereinafter referred to as samples #11 through #15). Film material: TAC (triacetylcellulose) with a thickness of 60 μm (manufactured by TacBright Optronics Corporation)

For the samples #11 to #14, the irradiation of the TAC films with linearly polarized ultraviolet light was performed using the photo-alignment treatment system 600A shown in FIG. 8A. In other words, light from a Xe excimer lamp (hereinafter referred to as 172 nm light) was linearly polarized through a VUV polarizer, and the polarized light was radiated to half the area of the TAC film.

The irradiation conditions on the samples #11 to #14 were different. The irradiation of the samples #11 and #12 of the TAC film with polarized VUV light of 172 nm was performed in the air atmosphere (in the air), and the irradiation of the samples #13 and #14 with polarized VUV light of 172 nm was performed in the N₂ purged atmosphere (oxygen concentration of 0.1% or less).

The irradiation amounts on the samples #11 and #12 were different: 1 J/cm² on the sample #11 and 5 J/cm² on the sample #12. Similarly, the irradiation amounts in the samples #13 and #14 were different: 1 J/cm² in the sample #13 and 5 J/cm² in the sample #14.

The sample #15 for comparison was simply prepared by rubbing, not by light irradiation. The rubbing was performed using cellulose (Cupra) fiber (Bencot (trademark): manufactured by Asahi Kasei). Specifically, the rubbing was performed by rubbing the surface of the TAC film in one direction using the above Bencot. Similar to the samples #11 to #14, the sample #15 was also subjected to rubbing treatment only in the half area of the film surface of the film.

### 1.2 Evaluation Results of the Samples #11 to #15

The evaluation system 500 described above was used to evaluate the photo-alignment state of the samples #11 to #15. Specifically, the liquid crystal cell structures 400 shown in FIG. 5A were fabricated using the respective samples of the test film 300, and these liquid crystal cell structures 400 were evaluated using the evaluation system 500 in FIG. 6.

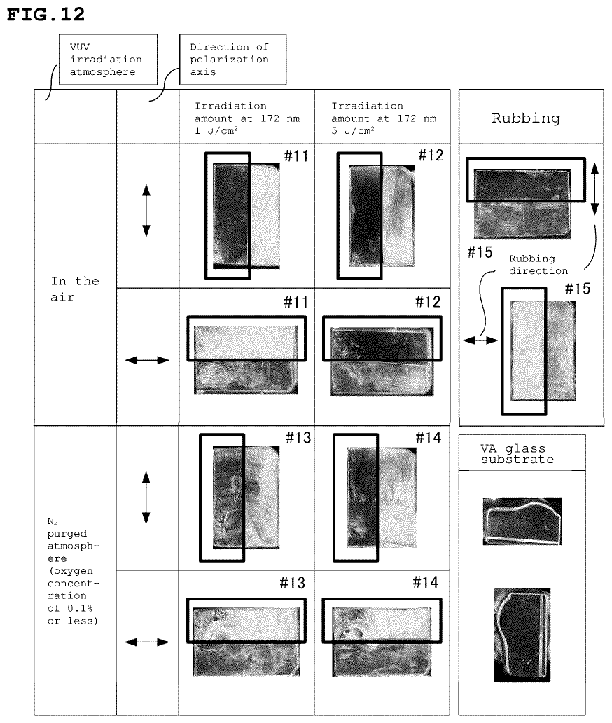

FIG. 12 is a table including photographs indicating the evaluation results of the samples #11 to #15 using the TAC film.

The photographs in the figure were obtained by disposing the liquid crystal cell structures with two different orientations in the evaluation system 500 and photographing the first polarizing film 510 of the evaluation system 500. The direction of the polarization axis in FIG. 12 is the direction of the polarization axis of the polarized VUV light radiated to the test film 300 and indicates a direction in which the liquid crystal cell structure 400 is disposed. In the samples #11 to #14, the black frames added to the photograph indicate the photo-alignment areas 302 of the test film 300.

Also, the polarization direction of the second polarizing film 520 of the evaluation system 500 is the up-down direction of the paper in FIG. 12, and the polarization direction of the first polarizing film 510 is the left-right direction of the paper in FIG. 12. In the case where the liquid crystal cell structure 400 functions as a TN cell structure, light from the backlight illumination 530 passes through the first polarizing film 510 and appears white in the photograph when the alignment direction of the liquid crystal at the interface between the test film 300 and the liquid crystal layer 410 (hereinafter simply referred to as the alignment direction of the liquid crystal layer 410) is the left-right direction of the paper.

### Sample #15

The area indicated by the black frame with respect to the sample #15 for comparison indicates an area where the test film 300 was subjected to the rubbing treatment. In the sample #15 for the comparison test, with which the simplified rubbing was performed, the alignment direction of the liquid crystal layer 410 is the same direction as the rubbing direction. Since the polarization direction of the second polarizing film 520 in the evaluation system 500 is the up-down direction on the paper and the polarization direction of the first polarizing film 510 is the left-right direction on the paper, the area inside the black frame appears white when the liquid crystal cell structure 400 is disposed such that the rubbing direction of the test film 300 in the sample #15 is the left-right direction on the paper.

### Sample #11

When the photo-alignment treatment was performed by irradiating the TAC film with polarized VUV light of 172 nm in the air atmosphere, it was observed that the alignment properties were imparted to the TAC film when the irradiation amount of light having a wavelength of 172 nm (linearly polarized VUV light) is 1 J/cm². In other words, when the liquid crystal cell structure is disposed such that the direction of the polarization axis of polarized VUV light radiated to the TAC film is up-down direction on the paper, the photo-alignment area 302 within the black frame appears black. However, when the liquid crystal cell structure is disposed such that the direction of the polarization axis of polarized VUV light radiated to the TAC film is left-right direction on the paper, the photo-alignment area 302 within the black frame appears white. Hence, it can be seen that the irradiation of polarized VUV light of 172 nm imparts alignment properties to the TAC film, and that the liquid crystal layer 410 is aligned in accordance with the alignment properties of the TAC film. Note that it is assumed that the alignment regulation force is relatively weak because some non-uniformity is observed.

Here, when the rubbing direction of the alignment film substrate 420 of the liquid crystal cell structure 400 is orthogonal to the direction of the polarization axis of polarized VUV light of 172 nm radiated to the TAC film, the area inside the black frame in FIG. 12 appears white. Since the second polarizing film 520 and the first polarizing film 510 are in a cross-nicol arrangement, the alignment direction of the liquid crystal layer 410 due to the alignment properties imparted to the TAC film is the left-right direction on the paper. In other words, the liquid crystal layer 410 is aligned in a direction parallel to the direction of the polarization axis of VUV light.

In the present embodiment, upon the irradiation with linearly polarized VUV light, the alignment properties are imparted to the resin base material 102, to which the photo-alignment treatment is to be subjected, due to the decomposition reaction associated with photo-activation. In conventional reports on photo-alignment methods using deep ultraviolet light having a wavelength longer than 200 nm, it has been assumed that, in the case of such decomposition-type materials, the liquid crystal is aligned in a direction orthogonal to the direction of the polarization axis of linearly polarized ultraviolet light radiated to the alignment film.

In contrast, in the TAC film according to the sample #11, the liquid crystal was aligned in a direction parallel to the direction of the polarization axis of linearly polarized VUV light radiated to the test film 300, and it has been confirmed that the sample #11 exhibits alignment characteristics different from that obtained by the conventional photo-alignment method using deep UV light.

### Sample #12

When the irradiation amount at a wavelength of 172 nm is 5 J/cm², the areas inside the black frames in FIG. 12 appear dark in the cases where the orientation of the liquid crystal cell structure was placed such that the direction of the polarization axis of the polarized ultraviolet light radiated to the TAC film is the up-down direction or the left-right direction on the paper. Hence, at a glance, no alignment properties appear to be imparted to the TAC film.

Here, the inventor hypothesized that when the irradiation amount of light having a wavelength of 172 nm (linearly polarized ultraviolet light) in the atmosphere increases, vertical alignment properties (hereinafter referred to as VA) is imparted due to the effects of oxidation on the TAC film surface.

To confirm this hypothesis, the glass substrate with the VA alignment film was extracted from a VA-type liquid crystal cell in place of the TAC film in the TN cell structure, and this glass substrate with the VA alignment film (hereinafter referred to as VA glass substrate) was disposed and evaluated in place of the test film (TAC). The result was shown in the photographs in the column labeled VA glass substrate in FIG. 12. When the TN cell structure with the VA glass substrate was placed in any direction in the evaluation system 500, however, the first polarizing film 510 appears nearly uniformly black. This suggests that the TAC film may have a vertical alignment state due to the effects of oxidation when the irradiation amount to the TAC film increases in the atmosphere.

### Sample #13, #14

When the TAC films were irradiated with linearly polarized ultraviolet light having a wavelength of 172 nm in the N₂ purged atmosphere (oxygen concentration of 0.1% or less), it was observed that the alignment properties were imparted to the TAC films both in the case of the irradiation amount of 1 J/cm² and 5 J/cm² of light having a wavelength of 172 nm (linearly polarized ultraviolet light).

When the irradiation of light at 172 nm (linearly polarized ultraviolet light) in the atmosphere was compared with the irradiation of light at 172 nm (linearly polarized ultraviolet light) in the N₂ purged atmosphere (oxygen concentration of 0.1% or less), it was observed that no alignment properties were imparted to the TAC film in the atmosphere (sample #12), but alignment properties were imparted to the TAC film in the N₂ purged atmosphere (oxygen concentration of 0.1% or less) (sample #14) in the case where the irradiation amount of light having a wavelength of 172 nm (linearly polarized ultraviolet light) is 5 J/cm². This indicates that oxygen functions to prevent the irradiation of light at 172 nm (linearly polarized ultraviolet light) from imparting the alignment properties.

Even when the irradiation amount of light having a wavelength of 172 nm (linearly polarized VUV light) was changed from 1 J/cm² to 5 J/cm² in the N₂ purged atmosphere, no significant change in the alignment state of the liquid crystal was observed although some improvement thereof was observed. In addition, although it was confirmed that the alignment properties were imparted to the TAC film, the alignment regulation force was considered to be weak in general because areas corresponding to the drop marks of liquid crystal were seen in the photographs.

The photographs of the portions corresponding to the areas of the TAC film not irradiated with light having a wavelength of 172 nm (linearly polarized VUV light) (areas not indicated by black frames) have different tints depending on the orientation of the liquid crystal cell structure. It is considered that alignment properties were weakly imparted to the TAC film by the orientation of some of the molecules constituting the TAC film in one direction. This orientation is produced in the tensile treatment during the manufacturing stage of the TAC film, for example, and can be seen in stretched films. A similar tendency is observed in other test films shown later.

In the case of the TAC films, the portion corresponding to the irradiation area of light having a wavelength of 172 nm (linearly polarized VUV light) and the portion corresponding to the non-irradiation area appear black-and-white inverted. This is considered to be caused by the fact that the alignment properties of the TAC film were overwritten by light having a wavelength of 172 nm (linearly polarized VUV light).

### 2. Experiment Using PET Film

### 2.1 Sample Preparation Conditions

Several samples were prepared using the PET films (hereinafter, referred to as samples #21 to #27). Film material: PET (polyethylene terephthalate) with a thickness of 100 μm (manufactured by Shanghai Plastech International Trading Co., Ltd.)

For the samples #21 to #26, the irradiation of the PET films with linearly polarized ultraviolet light was performed using the photo-alignment treatment system 600A shown in FIG. 8A.

The irradiation conditions on the samples #21 to #26 were different. For the samples #21 to #24, the irradiation of polarized VUV light having a wavelength of 172 nm to the PET film was performed in an air atmosphere (in the air), while for the samples #25 and #26, it was performed in the N₂ purged atmosphere (oxygen concentration of 0.1% or less).

In addition, the irradiation amounts on the samples #21 to #24 were different: 0.1 J/cm², 0.2 J/cm², 1 J/cm², and 5 J/cm², respectively. The irradiation amounts on the samples #25 and #26 were 1 J/cm² and 5 J/cm², respectively.

The sample #27 for comparison was prepared by simplified rubbing instead of the light irradiation. The rubbing technique was similar to that for the sample #15. The sample #27 was also subjected to rubbing treatment only in the half area of the film surface, which is similar to the samples #21 to #26.

### 2.2 Evaluation Results of the Samples #21 to #27

The evaluation system described above 500 was used for the evaluation of the photo-alignment state of the samples #21 to #27. The evaluation method is similar to that for the samples #11 to #15.

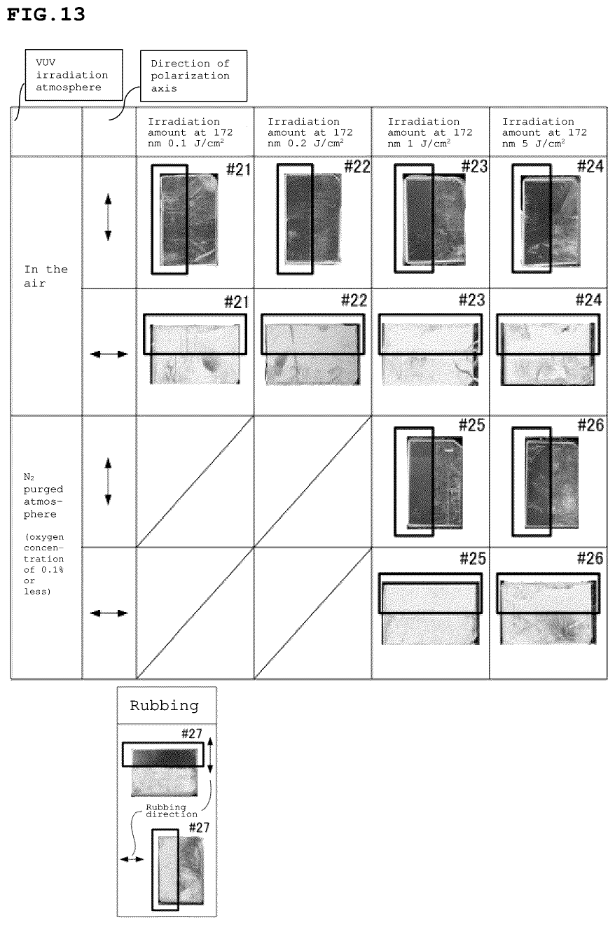

FIG. 13 is a table including the photographs of the samples #21 to #27 using PET films.

### Samples #21 to #26

In the case of samples #21 to #26, which are made of PET, the alignment properties were imparted to the test films (PET) when the irradiation of polarized ultraviolet light having a wavelength of 172 nm was performed in the atmosphere (#21 to #24) and the irradiation of polarized ultraviolet light having a wavelength of 172 nm was performed in the N₂ purged atmosphere (oxygen concentration of 0.1% or less) (#25 and #26).

In other words, when the orientation of the liquid crystal cell structure 400 was placed such that the direction of the polarization axis of polarized ultraviolet light radiated to the PET film is in the up-down direction on the paper, the areas inside the black frames in FIG. 13 appear black; however, when the orientation of the liquid crystal cell structure 400 was placed such that the direction of the polarization axis of polarized ultraviolet light radiated to the PET film is in the left-right direction on the paper, the areas inside the black frames appear white. Accordingly, it can be seen that the irradiation of polarized ultraviolet light at 172 nm imparts alignment properties to the PET film and that the liquid crystal is aligned in accordance with the alignment properties of the PET film.

In addition, the areas that appear white inside the black frame in FIG. 13 are almost uniformly white, indicating that the liquid crystal is well aligned, and the irradiation amount of light having a wavelength of 172 nm (linearly polarized ultraviolet light) in the atmosphere is nearly saturated at 0.2 mJ/cm² or more. This result is comparable to that of the sample #27 for the comparison test, which was subjected to the rubbing treatment.

Here, unlike the case of the TAC film, no influence of oxygen was observed on imparting the alignment properties to the PET film by the irradiation of light at 172 nm (linearly polarized ultraviolet light). Hence, the alignment properties of the liquid crystal are considered to be nearly saturated at the irradiation amount of 0.2 mJ/cm² or more of light having a wavelength of 172 nm (linearly polarized ultraviolet light).

In the case of the PET films, as is similar to the TAC films, the liquid crystal is aligned in a direction parallel to the direction of the polarization axis of linearly polarized VUV light radiated to the test film.

In the case of the PET film, compared to the case of the TAC film, the alignment properties were stronger in the area (area not indicated by the black frame) corresponding to the area not irradiated with light having a wavelength of 172 nm (linearly polarized ultraviolet light). In this case, the alignment direction of the liquid crystal due to the effects of the tensile treatment in the manufacturing stage of the PET film is the same as that of the liquid crystal in the area (the area indicated by the black frame) irradiated with light having a wavelength of 172 nm (linearly polarized ultraviolet light).

Although it is difficult to see in the photographs shown in FIG. 13, when the photographs are enlarged, it can be seen that the areas (areas indicated by the black frames) corresponding to the areas irradiated with light having a wavelength of 172 nm (linearly polarized VUV light) have a larger alignment regulation force than the areas (areas outside the black frames) corresponding to the areas not irradiated with light having a wavelength of 172 nm (linearly polarized VUV light). In addition, when the irradiation amount of light having a wavelength of 172 nm (linearly polarized VUV light) is 0.2 mJ/cm² or more, no drop mark of the liquid crystal can be seen in the areas indicated by the black frames.

### 3. Experiment Using COP Films

### 3.1 Sample Preparation Conditions

Several samples were prepared using the COP films (hereinafter referred to as samples #31 to #35). Film material: COP (Cyclo-Olefin Polymer) with a thickness of 100 μm (manufactured by ZEON Corporation)

For the samples #31 to #34, the irradiation of linearly polarized ultraviolet light to the COP films was performed using the photo-alignment treatment system 600A shown in FIG. 8A.

The irradiation conditions on the samples #31 to #34 were different. For the samples #31 and #32, the irradiation of COP film with polarized VUV light having a wavelength of 172 nm was performed in an air atmosphere (in the air), while for the samples #33 and #34, it was performed in the N₂ purged atmosphere (oxygen concentration of 0.1% or less).

In addition, the irradiation amounts on the samples #31 and #32 were different: 1 J/cm² and 5 J/cm², respectively. The irradiation amounts on the samples #33 and #34 were 1 J/cm² and 5 J/cm², respectively.

The sample #35 for comparison was prepared by simplified rubbing instead of the light irradiation. The sample #35 was subjected to rubbing treatment only in the half area of the film surface with the rubbing technique similar to that for the samples #15 and #27.

### 3.2 Evaluation Results of the Samples #31 to #35

The evaluation system 500 described above was used for the evaluation of the photo-alignment state of the samples #31 to #35. The evaluation method is similar to that for the samples #11 to #15.

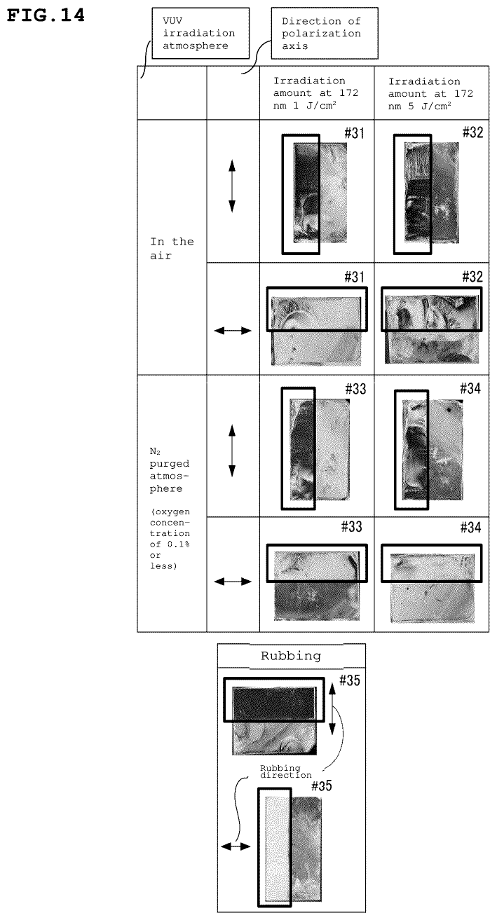

FIG. 14 is a table including the photographs of the samples #31 to #35 using COP films.

### Sample #31, #32

When the photo-alignment treatment was performed by irradiating the COP film with polarized ultraviolet light having a wavelength of 172 nm in the air, it was observed that the alignment properties were imparted to the sample #31, in which the irradiation amount of light having a wavelength of 172 nm (linearly polarized ultraviolet light) is 1 J/cm² to some extent; however, in comparison with the sample #35 for comparison test, which was subjected to rubbing treatment, the quality of the alignment properties was obviously not good. Even when compared to the TAC film, the alignment regulation force of the COP films was weak. In addition, it was observed that almost no alignment properties were imparted to the sample #32, in which the irradiation amount of light having a was 5 J/cm², nor was the state in which the vertical alignment is suggested, as was the case with the TAC film.

### Sample #33, #34

It was observed that the irradiation of linearly polarized ultraviolet light having a wavelength of 172 nm in the N₂ purged atmosphere (oxygen concentration of 0.1% or less) imparted the alignment properties to the COP films on both of the sample #33 with an irradiation amount of 1 J/cm² and the sample #34 with an irradiation amount of 5 J/cm², although the alignment regulation force was weak.

In other words, when the orientation of the liquid crystal cell structure was placed such that the direction of the polarization axis of the polarized ultraviolet light radiated to the COP films is in the up-down direction on the paper, the areas inside the black frames in FIG. 14 appear black; however, when the orientation of the liquid crystal cell structure was placed such that the direction of the polarization axis of the polarized ultraviolet light radiated to the COP films is in the left-right direction on the paper, the areas inside the black frames in FIG. 14 appear white. This indicates that the irradiation of polarized ultraviolet light having a wavelength of 172 nm imparts alignment properties to the COP films and that the liquid crystal is aligned in accordance with the alignment properties of the COP films.

As described above, in the case of the COP films the irradiation of linearly polarized ultraviolet light having a wavelength of 172 nm in the air imparts less alignment properties to the COP films than that in the N₂ purged atmosphere, as is similar to the TAC films. Hence, it is assumed that oxygen functions to prevent the irradiation of light at 172 nm (linearly polarized ultraviolet light) from imparting the alignment properties.

However, although it is observed that the irradiation of linearly polarized ultraviolet light at 172 nm imparts the alignment properties in the areas inside the black frames in FIG. 14, the drop marks of liquid crystal are also observed. Accordingly, the alignment regulation force of the liquid crystal is not sufficient, indicating that the alignment properties thereof are inferior to that of the TAC film.

In the COP films, it is noted that the liquid crystal is aligned in a direction parallel to the direction of the polarization axis of linearly polarized VUV light radiated to the test film, as is similar to the TAC films and PET films.

In the case of the COP film, compared to the case of TAC film and PET film, no alignment properties were observed in the area (area not indicated by the black frame) corresponding to the area not irradiated with light having a wavelength of 172 nm (linearly polarized ultraviolet light). Accordingly, in the case of the COP film, the material itself is considered to be in a state similar to glass with a random alignment direction.

### 4. Experiment Using PC Films

### 4.1 Sample Preparation Conditions

Several samples were prepared using the PC films (hereinafter referred to as samples #41 to #45). Film material: PC (polycarbonate) with a thickness of 100 μm (manufactured by Mitsubishi Engineering-Plastics Corporation)

For the samples #41 to #44, the irradiation of the PC films with linearly polarized ultraviolet light was performed using the photo-alignment treatment system 600A shown in FIG. 8A.

The irradiation conditions on the samples #41 to #44 were different. For the samples #41 and #42, the irradiation of the PC film with polarized VUV light having a wavelength of 172 nm was performed in an air atmosphere (in the air), while for the samples #43 and #44, it was performed in the N₂ purged atmosphere (oxygen concentration of 0.1% or less).

In addition, the irradiation amounts on the samples #41 and #42 were different: 1 J/cm² and 5 J/cm², respectively. The irradiation amounts on the samples #43 and #44 were 1 J/cm² and 5 J/cm², respectively.

The sample #45 for comparison was prepared by simplified rubbing instead of the light irradiation. The sample #45 was subjected to rubbing treatment only in the half area of the film surface with the rubbing technique similar to that for the samples #15 and #27.

### 4.2 Evaluation Results of the Samples #41 to #45

The evaluation system 500 described above was used for the evaluation of the photo-alignment state of the samples #41 to #45. The evaluation method is similar to that described above.

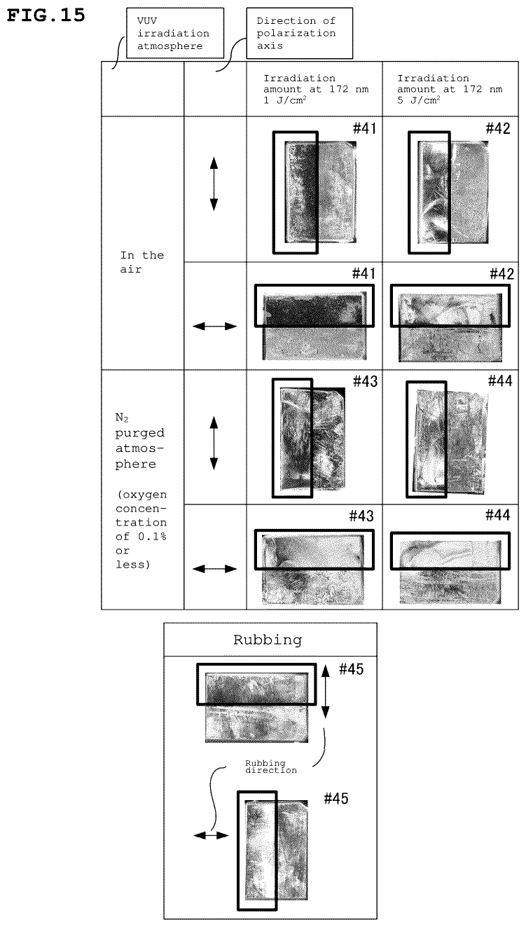

FIG. 15 is a table including the photographs of the samples #41 to #45 using the PC films.

### Sample #45

In the sample #45 for the comparison test that was subjected to the simplified rubbing, since the rubbing direction of the second polarizing film 520 is the up-down direction on the paper, thus the areas indicated by the black frames appear somewhat white when the liquid crystal cell structure 400 was placed such that the rubbing direction of the sample #45 is the left-right direction on the paper.

### Sample #41, #42

When the photo-alignment treatment was performed by irradiating the PC films with polarized ultraviolet light having a wavelength of 172 nm in the air, no alignment properties were imparted to the PC films on the sample #41, in which the irradiation amount of light having a wavelength of 172 nm (linearly polarized ultraviolet light) is 1 J/cm² and the sample #42, in which the irradiation amount thereof was 5 J/cm².

### Sample #43, #44

Meanwhile, when the PC films were irradiated with linearly polarized ultraviolet light having a wavelength of 172 nm in the N₂ purged atmosphere (oxygen concentration of 0.1% or less), it can be seen that the alignment properties were difficult to be imparted to both of the sample #43, in which the irradiation amount of 1 J/cm² of light having a and the sample #44, in which that of 5 J/cm² thereof, although a change was observed to some extent in both of the samples, compared to the area not irradiated with light having a wavelength of 172 nm.

In the sample #45, which was the PC film subjected to the rubbing treatment, the alignment properties of the liquid crystal in the rubbed area were not good. Hence, it is considered that the alignment properties are difficult to be imparted to the PC films by the rubbing treatment and the photo-alignment treatment.

### 5. Experiment on Wavelength Dependence

Experiments were conducted to examine the wavelength dependence of the irradiation light (polarized ultraviolet light) on the PET film among several films with different materials. In the previous evaluation, the PET film provided the best results in imparting the alignment properties by the irradiation with polarized ultraviolet light having a wavelength of 172 nm. The wavelength dependence on the polyimide (PI) film was also examined for comparison.

### 5.1 Sample Preparation Conditions

Several samples were prepared using the PET films and the PI films (hereinafter referred to as samples #51 to #59 and samples #61 to #64, respectively).

### Samples #51 to #59

The materials for samples #51 to #59 are as follows. Film material: PET (polyethylene terephthalate) with a thickness of 100 μm (manufactured by Shanghai Plastech International Trading Co., Ltd.)

For the samples #51, #52, #55, and #56, the irradiation of the PET films with linearly polarized ultraviolet light was performed using the photo-alignment treatment system 600A shown in FIG. 8A. The irradiation of the samples #51 and #55 was performed in the air, and the irradiation of the samples #52 and #56 was performed in the N₂ purged atmosphere (oxygen concentration of 0.1% or less).

For the samples #53 and #57, the PET films were irradiated with deep ultraviolet (DUV) light having a center wavelength of 222 nm, and the DUV light irradiation was performed using the photo-alignment treatment system 600B shown in FIG. 8B.

For the samples #54 and #58, the PET films were irradiated with deep ultraviolet (DUV) light having a wavelength of 254 nm, and the DUV light irradiation was performed using the photo-alignment treatment system 600C in FIG. 8C.

The irradiation amount on the samples #51 to #54 was 1 J/cm², and the irradiation amount on the samples #55 to #58 was 5 J/cm².

The sample #59 is a PC film for comparison test with simplified rubbing.

### Samples #61 to #64

The materials for samples #61 to #64 are as follows: PI (polyimide) layer deposited on a glass substrate (The PI layer was manufactured by Hitachi Chemical Co.)

For each of the samples #61 to #64, a glass substrate with a PI film as an alignment film (without rubbing treatment) was used.

For the samples #61 and #62, the irradiation of the PET films with linearly polarized ultraviolet light was performed using the photo-alignment treatment system 600A shown in FIG. 8A. For the sample #61, the irradiation was performed in the air; while for the sample #62, it was performed in the N₂ purged atmosphere (oxygen concentration of 0.1% or less).

For the sample #63, the PET film was irradiated with deep ultraviolet (DUV) light having a center wavelength of 222 nm, and the DUV light irradiation was performed using the photo-alignment treatment system 600B in FIG. 8B. For the sample #64, the PET film was irradiated with deep ultraviolet (DUV) light having a wavelength of 254 nm, and the irradiation of the PET film with linearly polarized ultraviolet light was performed using the photo-alignment treatment system 600C in FIG. 8C.

The irradiation amounts for the samples #61 to #64 were all 1 J/cm².

### 5.2 Evaluation Results of Wavelength Dependence

The evaluation system 500 described above was used to evaluate the samples #51 to #59 and #61 to #64. The evaluation method is as described above; however, and the samples #51 to #58 were photographed by fixing the orientation of the liquid crystal cell structure 400 including the samples #51 to #58 such that the direction of the polarization axis of polarized ultraviolet light radiated to the film was the left-right direction on the paper. The sample #59 was also photographed only when the direction of the simplified rubbing treated on the PET film was the left-right direction on the paper. In addition, the samples were photographed by fixing the orientation of the liquid crystal cell structure 400 including the samples #61 to #64 such that the direction of the polarization axis of polarized ultraviolet light radiated to the film was the up-down direction on the paper.

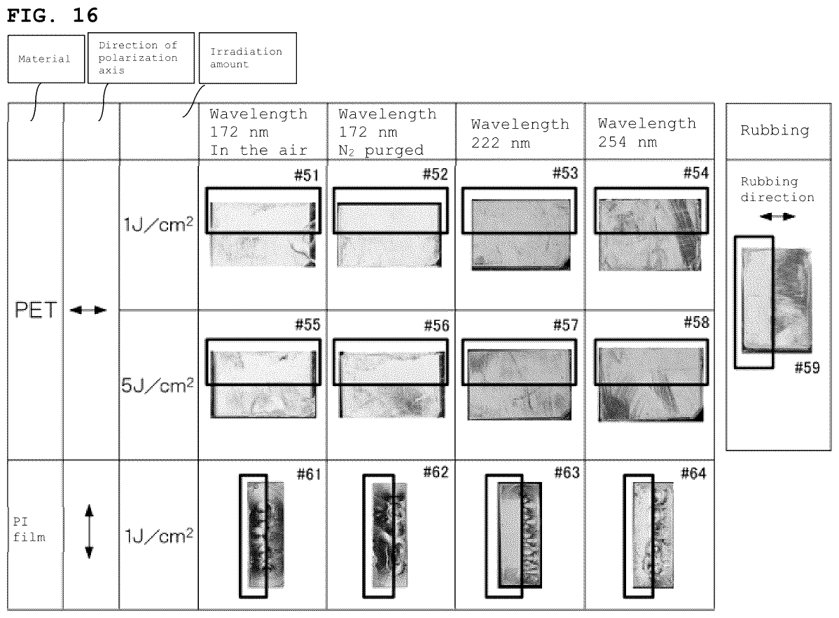

FIG. 16 is a table including the photographs of the samples #51 to #59 using the PET films and the samples #61 to #64 using the PI films.

### Samples #61 to #64

In the case of the glass substrates with the PI alignment film, it is known that in conventional reports, the irradiation of the PI alignment film with linearly polarized DUV light imparts alignment properties to the PI alignment film due to the decomposition reaction of PI, and aligns the liquid crystal in the direction orthogonal to the direction of the polarization axis of linearly polarized DUV light.

Hence, by orienting the direction of the liquid crystal cell structure 400 as described above, the liquid crystal cell structure 400 in the evaluation system 500 functions as a TN cell structure, allowing light from the backlight illumination 530 to pass through the area surrounded by the black frame of the PI layer shown in FIG. 16, which appears white in the photographs.

### Samples #51 to #58

In the case of the PET films, the alignment properties were imparted to the PET films when the irradiation with polarized ultraviolet light having a wavelength of 172 nm was performed, the irradiation with polarized ultraviolet light having a wavelength of 222 nm was performed, and the irradiation with polarized ultraviolet light having a wavelength of 254 nm was performed in the air and in the N₂ purged atmosphere (oxygen concentration of 0.1% or less). In particular, the irradiation with polarized ultraviolet light having a wavelength of 172 nm imparted the best alignment properties to the PET film. In addition, the alignment direction that has imparted to the PET film was parallel to the polarization axis independent of the wavelength. Since it is observed that the alignment direction with DUV light was same as that with VUV light, it was found for the first time that the present results were different from the reported results such that the direction of alignment properties was orthogonal to the DUV polarization axis for the PI films. This indicates that single irradiation is capable of producing the alignment properties and a pre-tilt angle simultaneously in the present method, whereas two irradiations were required to impart alignment properties with the orthogonal direction to the polyimide (PI) by the conventional DUV polarized light for producing a pre-tilt angle.

### Samples #61 to #64

In contrast, in the case of the glass substrates with PI alignment film, the alignment properties were imparted to the PI film in both of the sample #63, which was irradiated with polarized ultraviolet light having a wavelength of 222 nm, and the sample #64, which was irradiated with polarized ultraviolet light having a wavelength of 254 nm. In particular, the sample #63, which was irradiated with polarized ultraviolet light having a wavelength of 222 nm, exhibited better alignment properties to the PI alignment film. In this case, the alignment direction was orthogonal, as reported for the conventional polarized light at 254 nm. In contrast, the samples #61 and #62, which were irradiated with polarized ultraviolet light at 172 nm in the air and the N₂ purged atmosphere (oxygen concentration of 0.1% or less), respectively, imparted no alignment properties.

Accordingly, in the case of the glass substrates with PI alignment film, this suggests that there may be a difference in the alignment reaction (decomposition reaction) between the irradiation with the polarized ultraviolet light having a wavelength of 172 nm and the irradiation with the polarized ultraviolet light having a wavelength of 222 nm and 254 nm. Although the difference in the reaction is not always clear, it is considered that the photon energy of the polarized ultraviolet light having a wavelength of 172 nm is large enough to cleave not only a specific point of the main chain of PI material but also other points thereof to make the PI material disjointed and disordered.

### 6. Summary

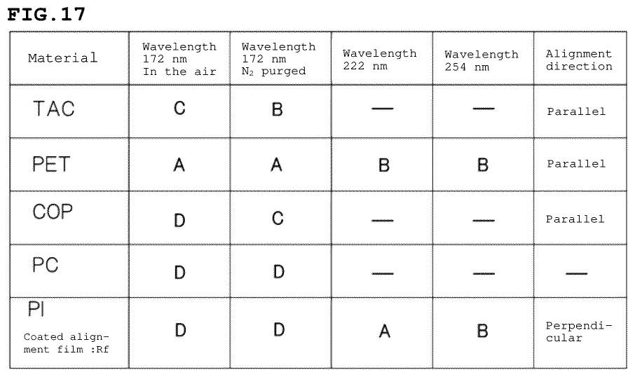

FIG. 17 is a table indicating a list of results for the samples prepared with the different materials and conditions. As mentioned above, it was found that the irradiation with linearly polarized ultraviolet light having a wavelength of 200 nm or less (wavelength of 172 nm) can impart the alignment properties to the base material itself. In the table, A, B, C, and D are marked in order from the best to the worst state of imparting alignment properties.

The extent to which the alignment properties are imparted highly depends on the base material; the order of the good state of imparting the alignment properties (order of good alignment regulation force and sensitivity) is PET, TAC, and COP. It is found that PET exhibited the state of imparting the alignment properties, the alignment regulation force, and the sensitivity to linearly polarized ultraviolet light radiated thereto the most favorably, and the alignment properties were well imparted to the PET when the irradiation amount (cumulative amount of light intensity) of linearly polarized ultraviolet light having a wavelength of 172 nm was 0.2 J/cm² or more.

It is also found that PET was not affected by oxygen during the irradiation of polarized ultraviolet light.

In contrast, TAC and COP were found to be affected by oxygen during the irradiation of polarized ultraviolet light; no alignment properties were imparted to TAC when the irradiation amount of polarized ultraviolet light having a wavelength of 172 nm was too large (e.g., 5 J/cm²) in the air atmosphere (oxygen-containing atmosphere). In the case of COP, it was found that the N₂ purged atmosphere (oxygen concentration of 0.1% or less) was necessary during the irradiation with polarized ultraviolet light having a wavelength of 172 nm. In addition, none of TAC and COP had a better state of imparting alignment properties than PET when irradiated with linearly polarized ultraviolet light having a wavelength of 200 nm or less (wavelength of 172 nm). In other words, TAC and COP had a weaker alignment regulation force than PET and were noticeably observed with unevenness.

Also, in the case of PC, no alignment properties were imparted by the irradiation with linearly polarized ultraviolet light having a wavelength of 200 nm or less (wavelength of 172 nm) in the air atmosphere and the N₂ purged atmosphere (oxygen concentration of 0.1% or less).

Meanwhile, when the wavelength dependence of the polarized ultraviolet light radiated to PET, which exhibited the state of imparting the alignment properties the most favorably, and the glass substrate with the PI layer as the alignment film as a reference were also investigated, it was found that the alignment properties were imparted to PET even by the polarized ultraviolet light having a wavelength of 222 nm and also by the polarized ultraviolet light having a wavelength of 254 nm. In the case of PET, the alignment properties were imparted better and the sensitivity to the polarized ultraviolet light was higher as the wavelength was shorter.

In contrast, in the case of the PI film for a reference (without rubbing treatment), no alignment properties were imparted when the wavelength of the irradiated polarized ultraviolet light was 200 nm or less (wavelength of 172 nm).

The alignment properties were imparted to the PI film when the above wavelength was 222 nm and 254 nm. In particular, the alignment properties imparted to the PI alignment film were more favorable and the sensitivity to polarized ultraviolet light was higher when the polarized ultraviolet light having a wavelength of 222 nm was radiated thereto.

It is noted that in the case of the substrates (PET, TAC, COP), the alignment direction of the liquid crystal is parallel to the polarization axis of polarized ultraviolet light radiated to each substrate, whereas in the case of the PI film (alignment film), to which the alignment properties were imparted by photo-decomposition reaction, the alignment direction of the liquid crystal is orthogonal to the polarization axis of polarized ultraviolet light radiated to the PI film.

Unlike the case of the conventional photo-alignment treatment of the PI film, it was found for the first time that the mechanism of imparting the alignment properties may be different (the location of the main chains and other chains that are cut in the decomposition reaction caused by the irradiation of polarized ultraviolet light may be different).

The control of the pre-tilt angle of the liquid crystal is important for the construction of optical films. In the case of the control of the pre-tilt angle, in the conventional deep-UV (e.g., 254 nm) decomposition-type photo-alignment treatment, the liquid crystal is aligned in a direction orthogonal to the polarization axis of polarized ultraviolet light. Hence, after the first irradiation of deep-UV polarized ultraviolet light, the second irradiation of deep-UV polarized ultraviolet light was necessary with changing the direction of the polarization axis by 90 degrees and the incident angle.

In the case of the present substrates, the liquid crystal is aligned in a direction parallel to the polarization axis of polarized ultraviolet light when irradiated with polarized ultraviolet light (especially at a wavelength of 200 nm or less). Hence only one irradiation with polarized ultraviolet light is necessary even when the pre-tilt angle is controlled as mentioned above. Therefore, the manufacturing process can be simplified and the optical element can be manufactured at low cost.

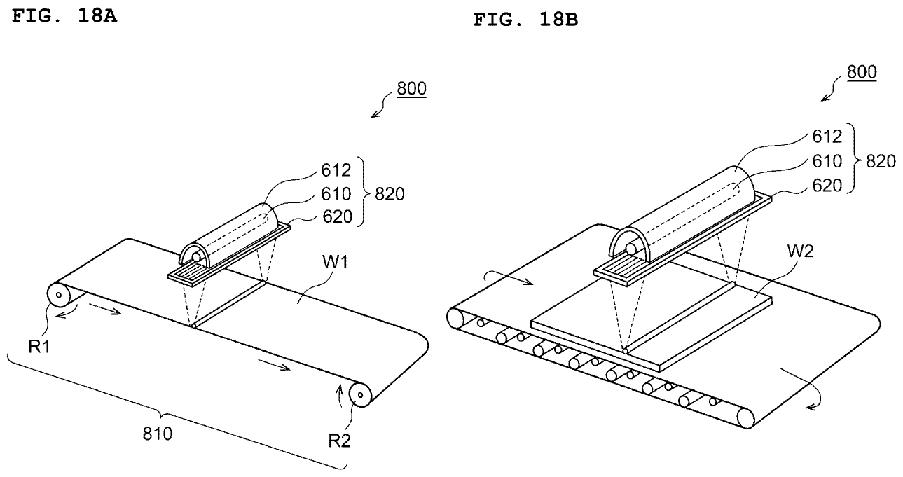

Hereinafter, a manufacturing apparatus that can be used to manufacture the optical component 100 will be described. FIGS. 18A and 18B are figures illustrating a manufacturing apparatus 800. The manufacturing apparatus 800 in FIG. 18A includes a conveying means 810 and an illumination device 820. The conveying means 810 conveys a workpiece W1, which corresponds to the base material 102 that is substantially transparent to light having a wavelength for which the optical component 100 is used. The workpiece W1 is wound in a roll shape, drawn from a feed roller R1, and taken up by a take-up roller R2 while being conveyed.

The illumination device 820 irradiates the workpiece W1 passing directly thereunder with linearly polarized ultraviolet light having a wavelength of 200 nm or less (or 222 nm, or 254 nm). The illumination device 820 can use the light sources shown in FIGS. 8A to 8C.

In the manufacturing apparatus 800 in FIG. 18B, the conveying means 810 conveys a workpiece W2, which is the plate-shaped base material 102. The conveying means 810 is a belt conveyor or a stage. The illumination device 820 emits light when the workpiece W2 passes directly thereunder and irradiates the workpiece W2 with linearly polarized ultraviolet light.

The workpieces W1 and W2 that have been treated by the manufacturing apparatus 800 shown in FIGS. 18A and 18B are subjected to subsequent treatment. In the subsequent treatment, the polymerizable liquid crystal compound 106 is applied to the workpieces by the coating means.

The present embodiments merely represent the principle and application of the present invention, and many variation examples and changes in the arrangement are allowed in the present embodiments to the extent that they do not depart from the idea of the present invention as defined in the claims.

According to the present disclosure, it is possible to impart the alignment properties to the base material itself, instead of imparting the alignment properties to an alignment film by conventionally subjecting the alignment film to the base material. Therefore, the alignment film coating process can be eliminated from the manufacturing process of optical components, thereby reducing the manufacturing time and manufacturing cost.

In addition, since no alignment film is needed in the manufacturing process described above, there is no need to use organic compounds that constitute the alignment film, which enables a clean manufacturing process for optical components, reducing the environmental impact.

This corresponds to Goal 9 of the UN-led Sustainable Development Goals (SDGs), “Build resilient infrastructure, promote inclusive and sustainable industrialization, and foster innovation” as well as significantly contributes to Target 9.4 thereof, “By 2030, upgrade infrastructure and retrofit industries to make them sustainable, with increased resource use efficiency and greater adoption of clean and environmentally sound technologies and industrial processes, all countries taking action in accordance with their respective capabilities.

The present disclosure relates to a method of manufacturing an optical component having a retardation layer.

### REFERENCE SIGNS LIST

100 Optical component
102 Base material
106 Polymerizable liquid crystal compound
108 Retardation layer
110 Laminate
200 Optical component
300 Test film
302 Photo-alignment area
304 Non photo-alignment area
400 Liquid crystal cell structure
410 Liquid crystal layer
420 Alignment film substrate
422 Glass substrate
424 Alignment film
500 Evaluation system
510 First polarizing film
520 Second polarizing film
530 Backlight illumination
600 Photo-alignment treatment system
610a Xe excimer lamp
610b KrCl excimer lamp
610c Deep-UV lamp
612 Reflector
614 Lamp house
620a VUV polarizer
620b, 620c DUV polarizer
622 Wavelength selection filter
630 Light-shielding plate
640 Purge box
650 Collimated light irradiation system
660 Stage

1. A method of manufacturing an optical component, the method comprising the steps of:
irradiating a base material that is substantially transparent to light having a wavelength for which the optical component is used with linearly polarized ultraviolet light having a wavelength of 200 nm or less;
stacking a polymerizable liquid crystal compound on the base material after the irradiation with the linearly polarized ultraviolet light; and
forming a retardation layer by allowing the polymerizable liquid crystal compound to be aligned in accordance with a state of the base material.

2. The method according to claim 1, wherein the retardation layer is aligned in a direction parallel to a polarization direction of the linearly polarized ultraviolet light.

3. The method according to claim 1, wherein a photochemical reaction of the base material induced by the irradiation with the linearly polarized ultraviolet light is a decomposition reaction.

4. The method according to claim 1, wherein the base material is made of one of PET (polyethylene terephthalate), TAC (triacetylcellulose), and cyclic olefin polymer.

5. The method according to claim 1, wherein the polymerizable liquid crystal compound has abnormal dispersion properties.

6. The method according to claim 1, wherein the irradiation with the linearly polarized ultraviolet light is performed in an inert gas atmosphere.

7. The method according to claim 1, wherein the base material is made of PET, and the step of the irradiation with the linearly polarized ultraviolet light is an irradiation with linearly polarized ultraviolet light having a wavelength of 222 nm or 254 nm instead of the linearly polarized ultraviolet light having a wavelength of 200 nm or less.

8. The method according to claim 1, wherein the base material is made of PET, and the irradiation with the linearly polarized ultraviolet light is performed in an atmosphere containing oxygen.

9. An apparatus of manufacturing an optical component, the apparatus comprising:
a conveying means that conveys a base material that is substantially transparent to light having a wavelength for which the optical component is used; and
an illumination device that irradiates the base material with linearly polarized ultraviolet light having a wavelength of 200 nm or less.

10. An optical component comprising:
a base material that is made of at least one of PET (polyethylene terephthalate), TAC (triacetylcellulose), and cyclic olefin polymer; and
a polymerizable liquid crystal compound that is directly stacked on the base material without any other layer and that is at least partially aligned in accordance with a state of the base material.
